(19) United States
(12) Patent Application Publication
(10) Pub. No.: US 2014/0329032 A1
(43) Pub. Date: Nov. 6, 2014

(54) DEVICE FOR IMPROVING THE UNIFORMITY OF THE FILM FOR PACKAGING AND METHOD FOR APPLYING THE SAME

(71) Applicant: EverDisplay Optronics (Shanghai) Limited, Shanghai (CN)

(72) Inventors: ChiaChen LI, Shanghai (CN); TeinWang HUANG, Shanghai (CN)

(73) Assignee: EverDisplay Optronics (Shanghai) Limited, Shanghai (CN)

(21) Appl. No.: 14/267,526

(22) Filed: May 1, 2014

(30) Foreign Application Priority Data
May 2, 2013 (CN) 201310159710.4

(51) Int. Cl. C23C 16/52; C23C 16/04

(52) U.S. Cl. CPC C23C 16/52; C23C 16/042
USPC 427/598; 118/723 R; 118/696

(57) ABSTRACT

A device and a method for improving uniformity of a film, which uses the controllable magnets instead of permanent magnets and controlling the magnetic polarity by a programmable control device, so that when the clamping frame is aligned with the mask, the magnetic polarity of the electromagnet is controlled to generate an alternating magnetic field which will affect the coating material sprayed from the evaporation source. With the help of the alternating magnetic field, the coating material will be evenly sprayed to a substrate. Consequently, uniformity of the film for coating and the yield of products are improved.

### CROSS-REFERENCE TO RELATED APPLICATIONS

The present application claims priority to and the benefit of Chinese Patent Application No. CN 201310159710.4, filed on May 2, 2013, the entire content of which is incorporated herein by reference.

### BACKGROUND OF THE INVENTION

1. Field of the Invention

The present disclosure relates to a device and a method for forming film, more specifically, to a device for improving uniformity of a film for packaging and a method for applying the same.

2. Description of the Related Art

Organic Light-Emitting Diode (“OLED” hereinafter) owns the characteristic of self-luminous, rapid time response, low cost, simple manufacture process, better resolution and high luminance, which is deemed as the emerging display technology. The upward film-coating for the packaging process is the key process in the OLED (Organic Light-Emitting Diode) technology, which affects the quality and production cost of the OLED products directly.

FIG. 1 shows the side view structure diagram of the upward film packaging device which comprises the permanent magnet in the clamping frame. As shown in FIG. 1, the upward film packaging device in the related art includes: a Mask 101, a Clamping Frame 103 and an Evaporation Source 105. Clamping Frame 103 is positioned above Evaporation Source 105; there are a plurality of coating areas (not shown in the figures) defined on the Mask 101; a Magnetic area is placed correspondingly to the positions of the portions of Clamping Frame 103 which are corresponding to the coating areas; the coating areas and the magnetic areas are in structure of arrays; a plurality of Permanent Magnet 104 are placed on both sides of each magnetic area.

FIG. 2 shows the distribution diagram of the magnetic polarity in the permanent magnet during the aligning operation by utilizing the upward film packaging device as shows in FIG. 1 to the clamping frame and mask. As shows in FIG. 2, when the aligning operation is performed to the clamping frame and the mask, since the mask is a metal mask, the magnetism of the permanent magnet is utilized, one row is N pole, and another row adjacent to the N pole is S pole, which enable the clamping frame to clamp the metal mask and to hold the solid substrate, by which achieves the tight clamping effects. Therefore, the clamping frame, the rigid substrate and the metal mask together form a sandwich-like structure, and the subsequent upward film packaging process can be performed.

FIG. 3 shows the distribution diagram of the magnetic lines in the permanent magnet during the process of coating by utilizing the upward film packaging device in FIG. 1. As shown in FIG. 3, during the evaporation process, since the permanent magnets in the both sides of the magnetic areas are magnetic, which will attract the ions for forming the film during the evaporation process, by which the film deposited on the solid substrate becomes thicker when the deposited film is closer to the both sides of the corresponding magnetic area. Consequently, it will affect the uniformity of the upward film packaging and lower the product yield.

A related art disclosed a mask holding mechanism and film forming apparatus. A mask holding mechanism is provided for a mask which covers a substrate mounted and held on a chuck of a film forming apparatus. The mask is formed of a magnetic material, and an opposite side of the chuck to the chuck plane which holds the substrate is dotted with magnets. The magnets may be arranged at lattice points forming a lattice.

The magnetic force in the central portion of the mask become weaker than the edges by distributing several magnets in the above mentioned invention, so that the mask could be tightly assembled to the gap between the glass substrate and the mask and to avoid the organic materials evaporated by the evaporation source entering into the gap between the mask and the glass substrate. However the above mentioned invention did not solve the problem that: since the permanent magnets in the both sides of the magnetic areas are magnetic which will adsorb the film forming ions during the process of coating, by which the film deposited on the solid substrate become thicker when the deposited film is closer to the both sides of the corresponding magnetic area. Consequently, it will affect the uniformity of the upward film packaging and lower the product yield.

Another related art disclosed a mask holding structure, a film forming method, an electro-optic device manufacturing method, and an electronic apparatus. A mask includes a base plate having opening parts, and chips having opening patterns and positioned in the opening parts of the base plate. The mask is arranged on a bottom surface of a bed plate with a substrate on which a film is to be formed sandwiched there between. The magnets are arranged on the bed plate, and plugs which are attracted to the magnets are arranged in the base plate.

Compared with the large-scale film substrate, although the film forming method in the above mentioned invention could form the thin film pattern with high precision, produce the electrical apparatus with good quality and improve the displaying quality. However the above mentioned invention did not solve the problem that: since the permanent magnets in the both sides of the magnetic areas are magnetic which will adsorb the film forming ions during the process of coating, by which the film deposited on the solid substrate become thicker when the deposited film is closer to the both sides of the corresponding magnetic area. Consequently, it will affect the uniformity of the upward film packaging and lower the product yield.

### SUMMARY OF THE INVENTION

An aspect of an embodiment of the present disclosure is directed toward a device for improving the uniformity of the film for packaging, which is capable of solving the problem that the thickness of the film for packaging is not uniform which causes a low yield of products.

Another aspect of an embodiment of the present disclosure is directed toward a method using the device.

An embodiment of the present disclosure provides a device for improving uniformity of a film, comprising:

an evaporation source to emit ions; and

a clamping frame spaced apart from the evaporation source to generate a controllable magnetic field so as to evenly distribute ions emitted from the evaporation source.

According to one embodiment of the present disclosure, wherein a plurality of controllable magnets are placed in the clamping frame to generate the controllable magnetic field.

According to one embodiment of the present disclosure, wherein the controllable magnetic field consists of a plurality of alternating magnetic fields.

According to one embodiment of the present disclosure, wherein the plurality of controllable magnets are a plurality of electromagnet units; and the alternating magnetic field is generated by the plurality of electromagnet units whose magnetic polarities are changed alternately.

According to one embodiment of the present disclosure, further comprising a programmable control device electrically connected to the plurality of electromagnet units;

wherein, the magnetic polarities of the plurality of electromagnet units are changed alternately under the control of the programmable control device.

According to one embodiment of the present disclosure, wherein each of the electromagnet units comprises iron cores and induction coils; and the magnetic polarity of each of the electromagnet units depends on the electric current direction which is controlled by the programmable control device and is generated in the induction coil.

According to one embodiment of the present disclosure, further comprising a metal mask fixed on the clamping frame; and a plurality of coating areas are in the mask; and a plurality of magnetic areas are in the clamping frame;

wherein, the plurality of coating areas are corresponding to the plurality of magnetic areas; and the plurality of electromagnet units are placed around each of the magnetic areas.

Another embodiment of the present disclosure provides a method for improving uniformity of a film, comprising:

(a) placing a clamping frame apart from the an evaporation source;

(b) generating a controllable magnetic field in the clamping frame; and

(c) initiating the evaporation source to emit ions;

wherein, the ions is evenly distributed by the controllable magnetic field.

According to another embodiment of the present disclosure, wherein a plurality of controllable magnets is placed in the clamping frame to generate the controllable magnetic field.

According to another embodiment of the present disclosure, wherein the controllable magnetic field consists of a plurality of alternating magnetic fields.

According to another embodiment of the present disclosure, wherein the alternating magnetic field are generated by a plurality of controllable magnets.

According to another embodiment of the present disclosure, wherein the controllable magnets are a plurality of electromagnet units whose magnetic polarities are changed alternately under an alternating electric field; and the plurality of electromagnet units are placed in the clamping frame.

According to another embodiment of the present disclosure, wherein the plurality of electromagnet units is electrically connected to a programmable control device; and the magnetic polarities of the plurality of electromagnet units are changed alternately under the control of the programmable control device.

According to another embodiment of the present disclosure, wherein each of the electromagnet units comprises iron cores and induction coils; and the magnetic polarity of each of the electromagnet units depends on the electric current direction which is controlled by the programmable control device and is generated in the induction coil.

According to another embodiment of the present disclosure, wherein there is a plurality of magnetic areas in the clamping frame; and the plurality of electromagnet units are placed around each of the magnetic areas.

According to another embodiment of the present disclosure, wherein a metal mask containing a plurality of coating areas is fixed on the clamping frame; and the plurality of coating areas are corresponding to the plurality of magnetic areas.

According to another embodiment of the present disclosure, in Step (c), an aligning operation is performed before initiating the evaporation source;

wherein, the aligning operation is performed according to the position relationship among the magnetic areas, the coating areas and the areas which will be coated.

### BRIEF DESCRIPTIONS OF THE DRAWINGS

The accompanying drawings, together with the specification, illustrate exemplary embodiments of the present disclosure, and, together with the description, serve to explain the principles of the present disclosure.

FIG. 1 shows the side view structure diagram of the upward film evaporation device which comprises permanent magnet in the clamping frame;

FIG. 2 shows the distribution diagram of the magnetic polarity in the permanent magnet during the aligning operation by utilizing the upward film evaporation device as shows in FIG. 1 to the clamping frame and mask;

FIG. 3 shows the distribution diagram of the magnetic lines in the permanent magnet during the evaporation process by utilizing the upward film evaporation device in FIG. 1;

FIG. 4 shows the side view structure diagram of the device which is used for improving the uniformity of film;

FIG. 5 shows the distribution diagram of the magnetic polarity of the permanent magnet during the aligning operation of the clamping frame with the mask by the device used to improve the uniformity of the film provided by the preferred embodiment according to the present disclosure;

FIG. 6 shows the distribution diagram of the magnetic lines in the electromagnet during the aligning operation of the clamping frame with the mask by the device used to improve the uniformity of film provided by the embodiment according to the present disclosure;

FIG. 7 shows the distribution diagram of the magnetic polarity of the electromagnet when using the device used to improve the uniformity of film to perform the evaporation process in the embodiment according to the present disclosure;

FIG. 8 shows the distribution diagram of the magnetic lines of force of the electromagnet when using the device used to improve the uniformity of film to perform the evaporation process in the embodiment according to the present disclosure.

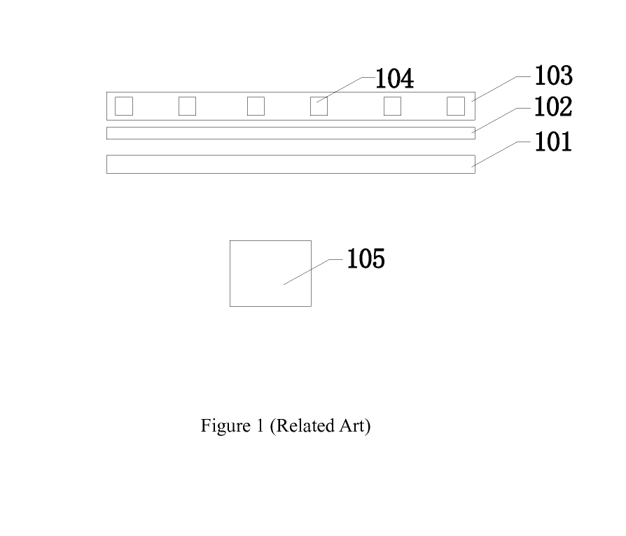

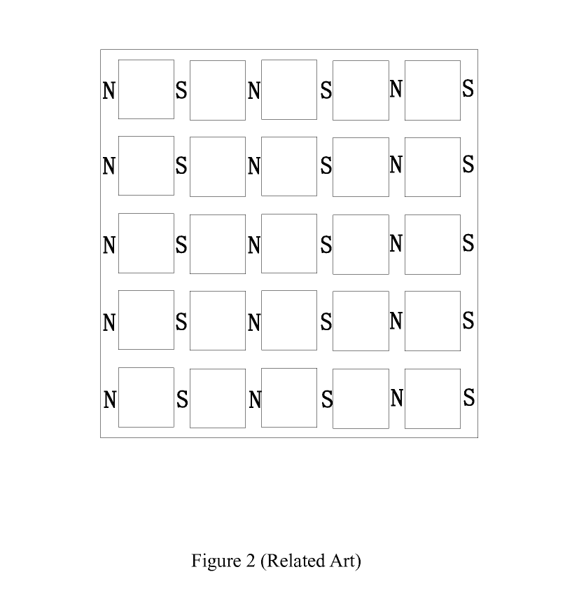

### DETAILED DESCRIPTIONS

The present disclosure will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the term “plurality” means a number greater than one.

Hereinafter, certain exemplary embodiments according to the present disclosure will be described with reference to the accompanying drawings.

In an embodiment of the present invention, the device for improving uniformity of a film comprises: an evaporation source to emit ions; and a clamping frame spaced apart from the evaporation source to generate a controllable magnetic field so as to evenly distribute ions emitted from the evaporation source. A plurality of controllable magnets is placed in the clamping frame to generate the controllable magnetic field. The controllable magnetic field consists of a plurality of alternating magnetic fields.

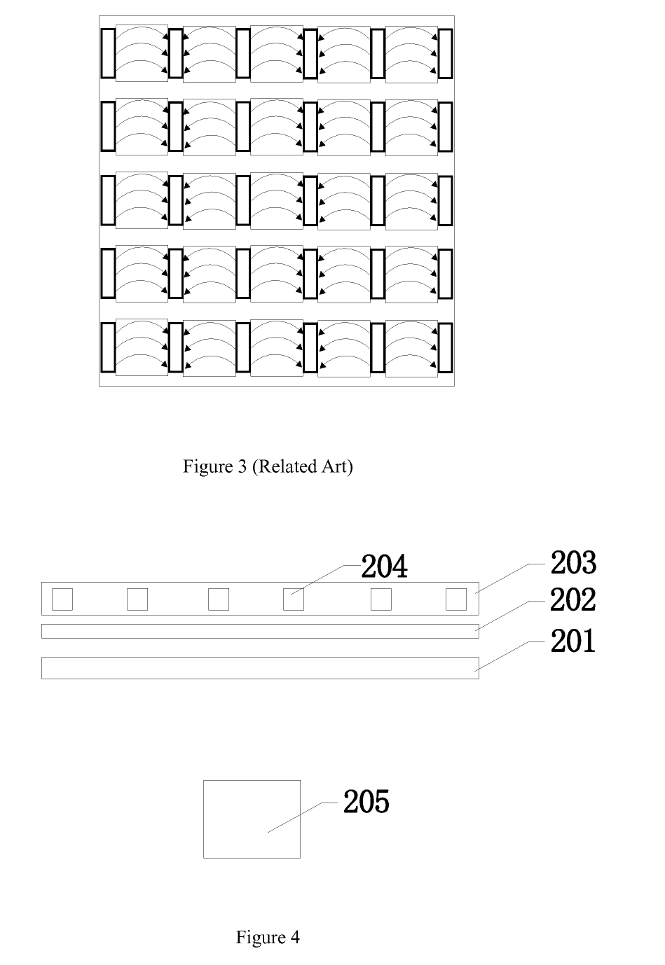

FIG. 4 shows the side view structure diagram of the device which is used for improving the uniformity of film. As shown in FIG. 4, the device further comprises a Metal Mask 201. Clamping Frame 203 is positioned above Evaporation Source 205, and the specific height of Clamping Frame 203 is depended on the process requirements. Several coating areas (not shown) are defined on Metal Mask 201. The magnetic areas (not shown) which corresponds to the coating areas are placed on Clamping Frame 203. The coating areas and magnetic areas is corresponding to the area to be coated with film on a sheet material; in this embodiment the sheet material is preferrablly selected as a Substrate 202 which can form a semiconductor product. Substrate 202, the coating areas and the magnetic areas are arranged in array structure. One or more controllable magnets are placed around each magnetic area; in this embodiment the controllable magnets are preferably selected as a plurality of Electromagnet Units 204. Metal Mask 201 is positioned between the evaporation source and Substrate 202 by Clamping Frame 203. Substrate 202 is hold by Clamping Frame 203 and is located between Clamping Frame 203 and Metal Mask 201. Clamping Frame 203, Substrate 202 and Metal Mask 201 together form a sandwich-like structure. Preferably, Substrate 202 is a rigid substrate, such as a glass substrate or a plastic substrate.

Moreover, the device further comprises a programmable control equipment. Electromagnet Unit 204 comprises iron cores and induction coils, the purpose of controlling the magnetic polarity of each of Electromagnet Units 204 is achieved by controlling the current direction in the induction coil. During the aligning operation of Clamping Frame 203 and Metal Mask 201, the magnetic polarity of each of Electromagnet Units 204 is controlled by the programmable control equipment. During the evaporation process, the control of the magnetic polarity of each of Electromagnet Unit 204 causes the mutual interference in several Electromagnet Units 204 for the purpose of magnetic disturbance, by which the magnetic lines of Electromagnet Unit 204 are evenly distributed in each position of Clamping Frame 203. Evaporation Source 205 generates the film forming ions, and a part of the ions is evaporated onto the coating areas of Metal Mask 201 which are corresponding to the central area of the area to be coated on Substrate 202, and another part of the ions is evenly attracted to the coating areas of Metal Mask 201 which are corresponding to the surroundings of the area to be coated on Substrate 202 due to the magnetism of Electromagnet Unit 204. Accordingly, the film with better uniformity can be acquired and the yields of the production can be further improved.

FIG. 5 shows the distribution diagram of the magnetic polarity of the permanent magnet during the aligning operation of the clamping frame with the mask by the device used for improving the uniformity of film provided by the preferred embodiment according to the present disclosure. As shown in FIG. 5, preferably, the evaporation process is an upward film evaporation process. Before performing the evaporation process, an aligning operation is performed to the clamping frame and the metal mask. When performing the alignment operation by utilizing the electromagnet on the clamping frame, the optimum situation is that the electromagnets on the both sides of the clamping frame are magnetic. By this time, the magnetic polarity of the electromagnet units placed around the magnetic areas are controlled by the programmable control equipment, which enables the magnetic polarity to distributes as FIG. 5, i.e., in the longitudinal direction of the electromagnet unit, a row of the electromagnet polarities are controlled to be N which means that the both polarities are N, and the polarities of the electromagnets which adjacents to the N polar electromagnet are S that means both polarities are S, by which the clamping frame and the metal mask tightly hold the hard substrate, and finally the alignment operation is performed successively.

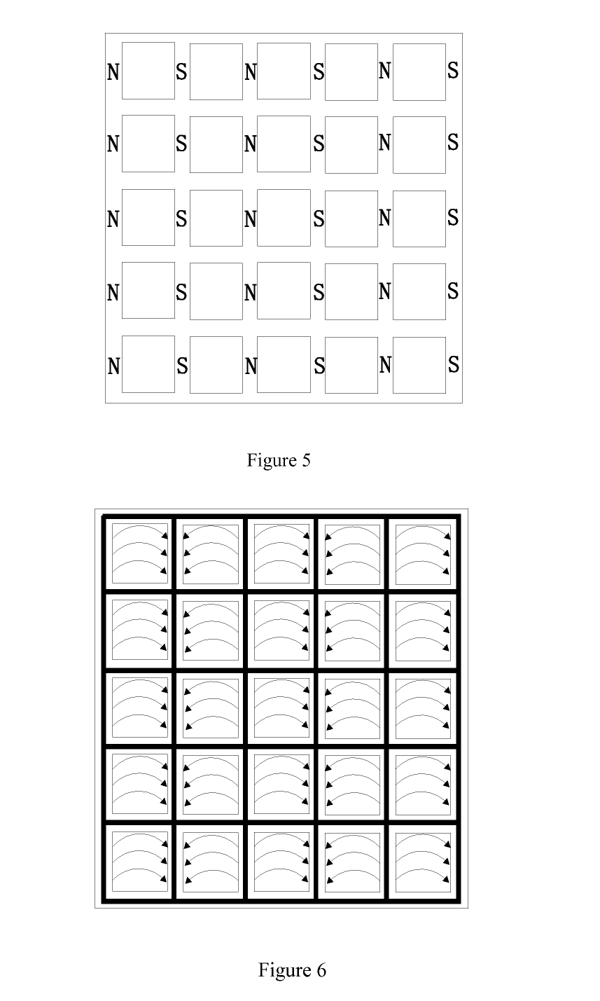

FIG. 6 shows the distribution diagram of the magnetic lines in the electromagnet during the aligning operation of the clamping frame with the mask by the device used for improving the uniformity of film provided by the embodiment according to the present disclosure. As shown in FIG. 6, preferably, the evaporation process is an upward film evaporation process. Before performing the evaporation process, an aligning operation is performed to the clamping frame and the metal mask. The electromagnet units are magnetic in the longitudinal direction of the electromagnet unit by utilizing the electromagnet units of the programmable control equipment around the magnetic area.

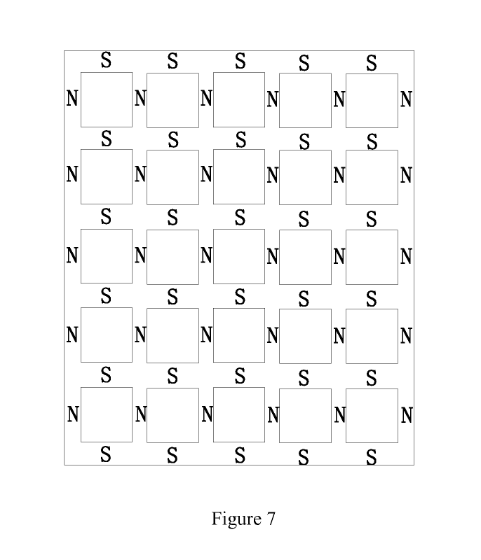

FIG. 7 shows the distribution diagram of the magnetic polarity of the electromagnet when using the device used to improve the uniformity of film to perform the evaporation process in the embodiment according to the present disclosure. As shown in FIG. 7, preferably, the evaporation process is an upward film evaporation process. When evaporation process is performed, initiating the evaporation source, meanwhile the polarities of the electromagnet units located around each of the magnetic areas are distributed as shown in FIG. 7 under the control of the programmable control equipment. The longitudinal directions of the electromagnet units are N poles, the horizontal directions of the electromagnet units are S pole, thereby the magnetism of the electromagnet units disturbs each other for the purpose of magnetism disturbance, by which the magnetic lines of electromagnet unit are evenly distributed in each position of the clamping frame. The evaporation source evaporates the film forming ions, and a part of the ions is evaporated onto the coating areas of the metal mask which corresponds to the central area of the area needs to be coated on the substrate, and another part of the film forming ions is evenly attracted to the coating areas of the metal mask which corresponds to the areas around the central area on the substrate. Accordingly, the film with better uniformity can be achieved and the yields of the production can be improved. Preferably, The substrate is a rigid substrate, such as a glass substrate or a plastic substrate.

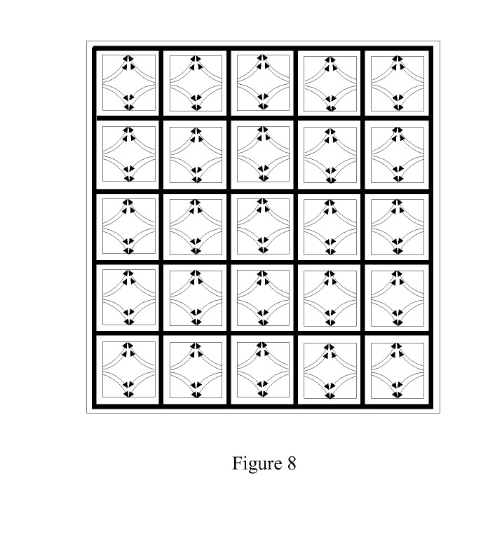

FIG. 8 shows the distribution diagram of the magnetic lines of force of the electromagnet when using the device used to improve the uniformity of film to perform the evaporation process in the embodiment according to the present disclosure. As shown in FIG. 8, preferably, the evaporation process is an upward film evaporation process. The magnetic polarities of the electromagnet units placed around the magnetic areas are controlled by the programmable control equipment, which enables the magnetic lines of the electromagnet unit to distribute as shown in FIG. 8, by which the lines are evenly distributed in each position of the clamping frame. In the evaporation process, the evaporation source evaporates the film forming ions, and a part of the ions is evaporated onto the mask areas of the metal mask which corresponds to the central area of the area that will be coated on the substrate, and another part of the film coating ions is evenly attracted to the coating areas of the metal mask which corresponds to the areas around the central area on the substrate. Therefore, the film with better uniformity can be achieved and the yields of the production can be improved. Preferably, the substrate is a rigid substrate, such as a glass substrate or a plastic substrate.

In conclusion, the above-mentioned solutions replaced the permanent magnet in the related art to the electromagnet, by which during the upward film evaporation process, when the evaporation process is performed, the magnetic polarity of the electromagnet is controlled to generating the magnetic disturbance, therefore the magnetic lines of the electromagnet are evenly distributed in each position of the coating areas. Consequently, it solve the problems as follows: during the evaporation process in related art, since the magnet in the both sides of the magnetic area are magnetic which will attract the film ions, which causes that the coated film becomes thicker while the distance between the film and the magnetic area of the magnet is closer, and the coated film is on the both sides of the areas that will be coated in the rigid substrate. The above-mentioned solutions improves the uniformity of the film after the upward film evaporation process, as well as the yield of production.

While the present disclosure has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A device for improving uniformity of a film, comprising:
an evaporation source to emit ions; and
a clamping frame spaced apart from the evaporation source to generate a controllable magnetic field so as to evenly distribute ions emitted from the evaporation source.

2. The device as claimed in claim 1, wherein a plurality of controllable magnets are placed in the clamping frame to generate the controllable magnetic field.

3. The device as claimed in claim 2, wherein the controllable magnetic field consists of a plurality of alternating magnetic fields.

4. The device as claimed in claim 3, wherein the plurality of controllable magnets are a plurality of electromagnet units; and the alternating magnetic field is generated by the plurality of electromagnet units whose magnetic polarities are changed alternately.

5. The device as claimed in claim 4, further comprising a programmable control device electrically connected to the plurality of electromagnet units;
wherein, the magnetic polarities of the plurality of electromagnet units are changed alternately under the control of the programmable control device.

6. The device as claimed in claim 5, wherein each of the electromagnet units comprises iron cores and induction coils; and the magnetic polarity of each of the electromagnet units depends on the electric current direction which is controlled by the programmable control device and is generated in the induction coil.

7. The device as claimed in claim 6, further comprising a metal mask fixed on the clamping frame; and a plurality of coating areas are in the mask; and a plurality of magnetic areas are in the clamping frame;
wherein, the plurality of coating areas are corresponding to the plurality of magnetic areas; and the plurality of electromagnet units are placed around each of the magnetic areas.

8. A method for improving uniformity of a film, comprising:
(a) placing a clamping frame apart from the an evaporation source;
(b) generating a controllable magnetic field in the clamping frame; and
(c) initiating the evaporation source to emit ions;
wherein, the ions is evenly distributed by the controllable magnetic field.

9. The device as claimed in claim 8, wherein a plurality of controllable magnets are placed in the clamping frame to generate the controllable magnetic field.

10. The device as claimed in claim 9, wherein the controllable magnetic field consists of a plurality of alternating magnetic fields.

11. The method as claimed in claim 10, wherein the alternating magnetic field is generated by a plurality of controllable magnets.

12. The method as claimed in claim 11, wherein the controllable magnets are a plurality of electromagnet units whose magnetic polarities are changed alternately under an alternating electric field; and the plurality of electromagnet units are placed in the clamping frame.

13. The method as claimed in claim 12, wherein the plurality of electromagnet units is electrically connected to a programmable control device; and the magnetic polarities of the plurality of electromagnet units are changed alternately under the control of the programmable control device.

14. The method as claimed in claim 13, wherein each of the electromagnet units comprises iron cores and induction coils; and the magnetic polarity of each of the electromagnet units depends on the electric current direction which is controlled by the programmable control device and is generated in the induction coil.

15. The method as claimed in claim 14, wherein there is a plurality of magnetic areas in the clamping frame; and the plurality of electromagnet units are placed around each of the magnetic areas.

16. The method as claimed in claim 15, wherein a metal mask containing a plurality of coating areas is fixed on the clamping frame; and the plurality of coating areas are corresponding to the plurality of magnetic areas.

17. The method as claimed in claim 16, in Step (c), an aligning operation is performed before initiating the evaporation source;
wherein, the aligning operation is performed according to the position relationship among the magnetic areas, the coating areas and the areas which will be coated.
